(19) United States
(12) Patent Application Publication
(10) Pub. No.: US 2014/0375852 A1
(43) Pub. Date: Dec. 25, 2014

(54) SOLID-STATE IMAGING APPARATUS, METHOD OF MANUFACTURING THE SAME, CAMERA, IMAGING DEVICE, AND IMAGING APPARATUS

(71) Applicant: CANON KABUSHIKI KAISHA, Tokyo (JP)

(72) Inventor: Masaya Ogino, Kawasaki-shi (JP)

(73) Assignee: CANON KABUSHIKI KAISHA, Tokyo (JP)

(21) Appl. No.: 14/294,465

(22) Filed: Jun. 3, 2014

(30) Foreign Application Priority Data
Jun. 20, 2013 (JP) 2013-129999
Jun. 20, 2013 (JP) 2013-130000

(51) Int. Cl. H01L 27/146; H04N 5/232

(52) U.S. Cl. CPC H01L 27/14627; H04N 5/23212; H01L 27/14621; H01L 27/14623
USPC 348/294; 257/432; 438/69

(57) ABSTRACT

A solid-state imaging apparatus comprising a pixel array, in which a pixel for imaging including a photoelectric conversion portion formed on a semiconductor substrate and a pixel for focus detection including a photoelectric conversion portion formed on the semiconductor substrate are arranged, wherein the pixel for imaging and the pixel for focus detection each include a member including an insulating layer formed on the photoelectric conversion portion and a shielding portion, and a microlens provided on the member, and the member of at least one of the pixel for imaging and the pixel for focus detection includes a flat plate-like member having a refractive index different from a refractive index of the insulating layer.

### BACKGROUND OF THE INVENTION

1. Field of the Invention

The present invention relates to a solid-state imaging apparatus, a method of manufacturing the same, a camera, an imaging device, and an imaging apparatus.

2. Description of the Related Art

An imaging system such as a digital camera can use a solid-state imaging apparatus including a pixel array of pixels for imaging and pixels for focus detection, each having a photoelectric conversion portion, for the miniaturization of the imaging system. The imaging performance of a pixel for imaging improves when focusing incident light passing through the microlens to near the photoelectric conversion portion. A pixel for focus detection uses a structure having a shielding portion for pupil division to perform focus detection based on a phase-difference detection method. The focus detection accuracy of this pixel improves when forming an image of incident light passing through the microlens at the position of the shielding portion.

### SUMMARY OF THE INVENTION

The present invention provides a technique advantageous for higher performance of a solid-state imaging apparatus including pixels for imaging and pixels for focus detection.

One of the aspects of the present invention provides a solid-state imaging apparatus comprising a pixel array, in which a pixel for imaging including a photoelectric conversion portion formed on a semiconductor substrate and a pixel for focus detection including a photoelectric conversion portion formed on the semiconductor substrate are arranged, wherein the pixel for imaging and the pixel for focus detection each include a member including an insulating layer formed on the photoelectric conversion portion and a shielding portion, and a microlens provided on the member, and the member of at least one of the pixel for imaging and the pixel for focus detection includes a flat plate-like member having a refractive index different from a refractive index of the insulating layer.

Further features of the present invention will become apparent from the following description of exemplary embodiments with reference to the attached drawings.

### BRIEF DESCRIPTION OF THE DRAWINGS

FIG. 1 is a block diagram for explaining an example of the arrangement of a solid-state imaging apparatus;

FIG. 2 is a circuit diagram for explaining an example of the circuit configuration of a pixel;

FIGS. 3A1, 3A2, 3B1, and 3B2 are views for explaining an example of the structure of a pixel in the first embodiment;

FIGS. 4A1, 4A2, 4B1, and 4B2 are views for explaining reference examples of the structures of a pixel for imaging and a pixel for focus detection;

FIGS. 5A1 to 5A3 and 5B1 to 5B3 are views each for explaining an example of a pupil image on a plane of the shielding portion of a pixel for focus detection;

FIG. 6 is a view for explaining another reference example of the structure of a pixel for focus detection;

FIGS. 7A to 7D are views for explaining another example of the first embodiment;

FIGS. 8A and 8B are views for explaining an example of the structure of a pixel in the second embodiment;

FIGS. 9A and 9B are views for explaining an example of the structure of a pixel in the third embodiment;

FIGS. 10A and 10B are views for explaining an example of the structure of a pixel in the fourth embodiment;

FIGS. 11A and 11B are views for explaining reference examples of the structures of a pixel for imaging and a pixel for focus detection;

FIG. 12 is a view for explaining an example of the sectional structure of a solid-state imaging apparatus;

FIGS. 13A to 13D are views each for explaining an example of the sectional structure of the solid-state imaging apparatus;

FIG. 14 is a graph for explaining the incident angle dependence of the amount of leakage light to an adjacent pixel;

FIG. 15 is a graph for explaining the amounts of change in the amount of leakage light to adjacent pixels depending on lens structures;

FIG. 16 is a view for explaining the amounts of leakage light to an adjacent pixel depending on different lens shapes;

FIGS. 17A and 17B are views for explaining an example of the structure of a pixel in the fifth embodiment;

FIG. 18 is a view for explaining an example of the sectional structure of the solid-state imaging apparatus according to the first embodiment;

FIGS. 19A and 19B are views for explaining an example of the structure of a pixel in the sixth embodiment;

FIGS. 20A to 20D are views for explaining another example of the sixth embodiment; and

FIGS. 21A and 21B are views for explaining an example of the structure of a pixel in the seventh embodiment.

### DESCRIPTION OF THE EMBODIMENTS

(Arrangement of Solid-State Imaging Apparatus)

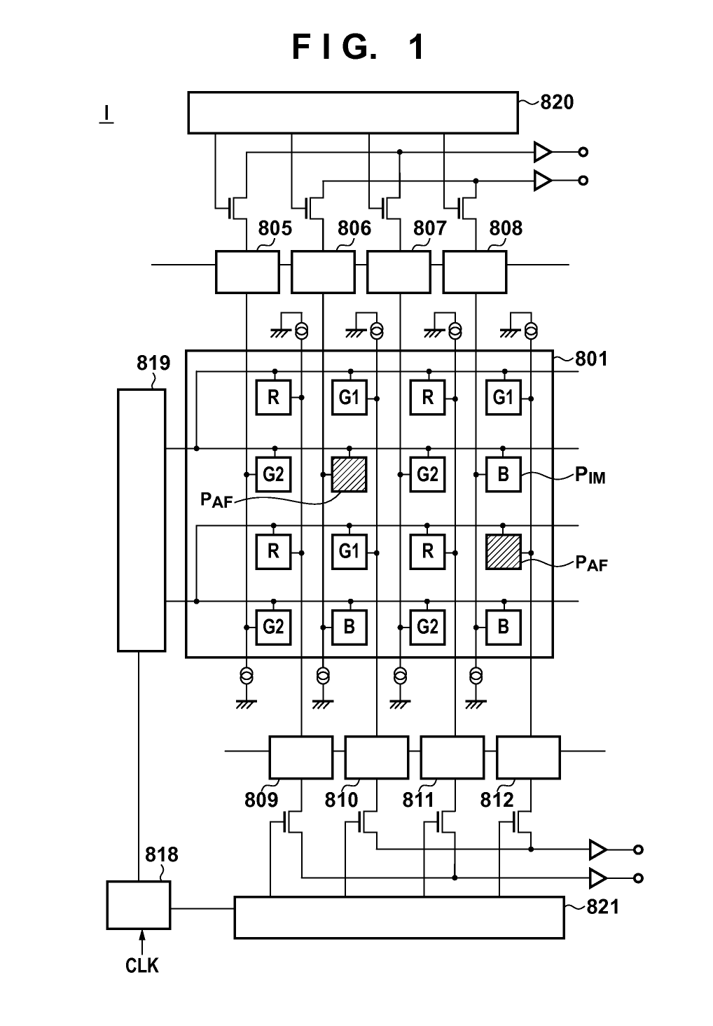

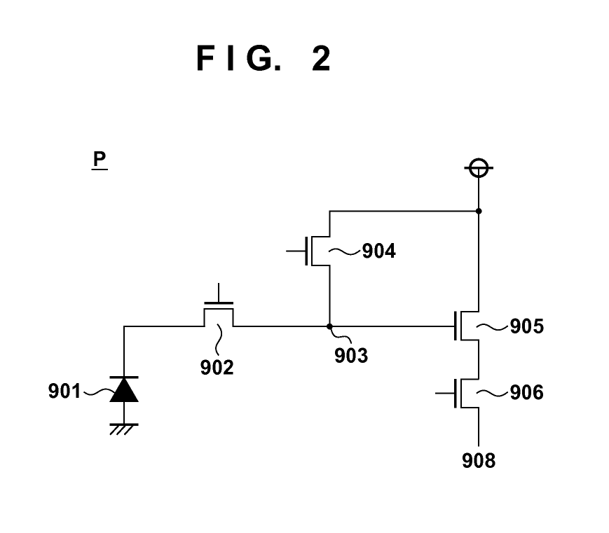

An example of the arrangement of a solid-state imaging apparatus I will be described with reference to FIGS. 1 and 2. The solid-state imaging apparatus I includes a pixel array 801, a plurality of column signal processing circuits 805 to 812, a row selecting control circuit 819, horizontal scanning circuits 820 and 821, and a timing control circuit 818. The pixel array 801 includes a plurality of pixels P (pixels P_{IM} for imaging and pixels P_{AF} for focus detection) arranged on the same substrate. For the sake of easy description, FIG. 1 shows the pixel array 801 in a 4 row×4 column matrix. The pixels P_{IM} for imaging are arranged in a Bayer arrangement. FIG. 1 exemplarily shows red pixels R, blue pixels B, and green pixels G1 and G2.

The plurality of column signal processing circuits 805 to 812 are arranged in correspondence with the respective columns of the pixel array 801. In this case, the column signal processing circuits 805 to 808 are arranged in correspondence with the pixels P on the even-numbered rows of the respective rows of the pixel array 801. The column signal processing circuits 809 to 812 are arranged in correspondence with the pixels P on the odd-numbered rows of the respective rows.

The timing control circuit 818 outputs a control signal to the row selecting control circuit 819 and the horizontal scanning circuits 820 and 821 in response to a clock signal CLK. The row selecting control circuit 819 outputs a control signal to the pixel array 801 based on a signal from the timing control circuit 818, and drives the pixels P at least for each row to read out pixel signals from the pixel array 801. The respective pixel signals from the pixel array 801 undergo predetermined signal processing in the column signal processing circuits 805 to 812. The processed signals are output to the outside by horizontal transferring in response to signals from the horizontal scanning circuit 820 or 821.

For example, an external signal processor processes signals, of the pixels signals from the pixel array 801, which are output from the respective pixels P_{IM} for imaging to obtain image data. In addition, of the pixel signals from the pixel array 801, signals from the respective pixels P_{AF} for focus detection are used for focus detection processing based on a phase-difference detection method. It is possible to focus on a desired object by, for example, driving an imaging lens motor to adjust the position of the imaging lens based on the defocus amount obtained by the focus detection processing.

FIG. 2 shows an example of the circuit configuration of the pixel P (the image P_{IM} for imaging or the pixel P_{AF} for focus detection) of the solid-state imaging apparatus I. The pixel P includes a photoelectric conversion portion 901 (for example, a photodiode), a transfer transistor 902, a floating diffusion region 903, a reset transistor 904, a source follower transistor 905, and a selecting transistor 906. The photoelectric conversion portion 901 generates and accumulates charges (electrons or holes) of an amount corresponding to the amount of light received. The transfer transistor 902 transfers the accumulated charges to the floating diffusion region 903 in response to the activation of the control signal supplied to the gate terminal of the transfer transistor 902. The amount of current flowing in the source follower transistor 905 changes in accordance with a fluctuation in the amount of charges transferred to the floating diffusion region 903. The selecting transistor 906 outputs a pixel signal corresponding to the amount of current in the source follower transistor 905 to a column signal line 908 in response to the activation of the control signal supplied to the gate terminal of the selecting transistor 906. The row selecting control circuit 819 described above selectively reads out pixel signals and sequentially outputs the signals to external units (for example, the signal processor) via the column signal processing circuits 805 to 812 provided for the respective columns by horizontal transferring by the horizontal scanning circuit 820 or 821. Note that the reset transistor 904 resets the potential of the floating diffusion region 903 in response to the activation of the control signal supplied to the gate terminal of the reset transistor 904.

Before each embodiment for the present invention is explained, in order to understand the present invention well, a first reference example and a second reference example are shown in the following.

### First Reference Example

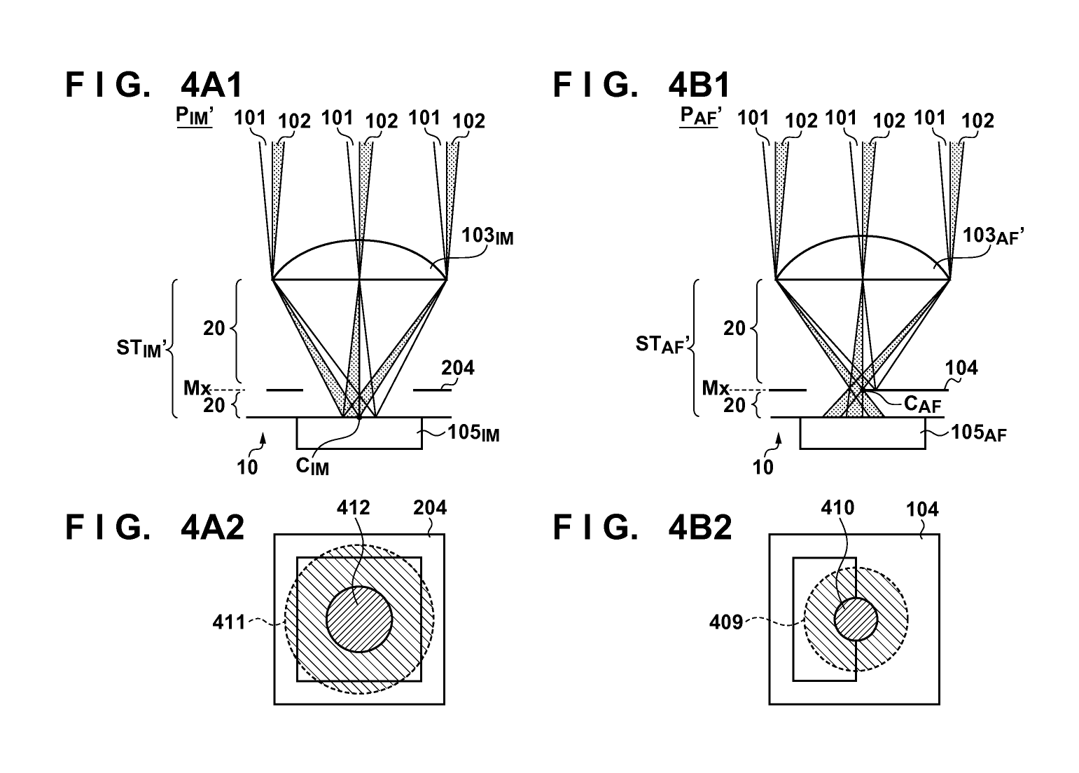

A case of a pixel P_{IM}′ for imaging and a pixel P_{AF}′ for focus detection will be described as the first reference example with reference to FIGS. 4A1 to 6. FIG. 4A1 schematically shows the sectional structure of the pixel P_{IM}′ for imaging. FIG. 4B1 schematically shows the sectional structure of the pixel P_{AF}′ for focus detection. In this reference example, the microlens 103_{AF}′ of the pixel P_{AF}′ has a larger curvature (height) than the microlens 103_{IM} of the pixel P_{IM}′. In this reference example, the apparatus adjusts the image forming position C_{AF} to a desired position by using the microlens 103_{AF}′ provided in the pixel P_{AF} for focus detection.

FIG. 4A2 schematically shows the sectional structure of the pixel P_{IM}′ for imaging on a plane of the interconnection layer Mx. More specifically, FIG. 4A2 schematically shows the shielding portion 204 and the pupil image (the image of the pupil) formed on a plane of the interconnection layer Mx by the pupil of the external imaging lens. The shielding portion 204 is arranged in a peripheral region of the pixel P_{IM}′ for imaging or a boundary region with an adjacent pixel and has an opening in a middle region so as to guide light entering the pixel P_{IM}′ for imaging to the photoelectric conversion portion 105_{IM} while preventing color mixture with the adjacent pixel. For the sake of easy description, FIG. 4A2 shows the shielding portion 204 integrally formed along the outer edge of the pixel P_{IM}′ for imaging. However, the shielding portion 204 is only required to be arranged in a peripheral region of the pixel P_{IM}′ for imaging or on its portion. FIG. 4B2 schematically shows the sectional structure of the pixel P_{AF}′ for focus detection on a plane of the interconnection layer Mx. More specifically, FIG. 4B2 schematically shows the shielding portion 104 and the pupil image formed on a plane of the interconnection layer Mx by the microlens 103.

In this reference example in which the pixel P_{IM}′ for imaging and the pixel P_{AF}′ for focus detection are arranged, the pixel P_{IM}′ for imaging differs in image magnification from the pixel P_{AF}′ for focus detection. For example, both a pupil image 411 formed on a plane of the shielding portion 204 and a pupil image 409 formed on a plane of the shielding portion 104 are pupil images corresponding to, for example, an f-number of 1.2 and formed at different magnifications. Both a pupil image 412 formed on plane of the shielding portion 204 and a pupil image 410 formed on a plane of the shielding portion 104 are pupil images corresponding to, for example, an f-number of 5.6 and formed at different magnifications.

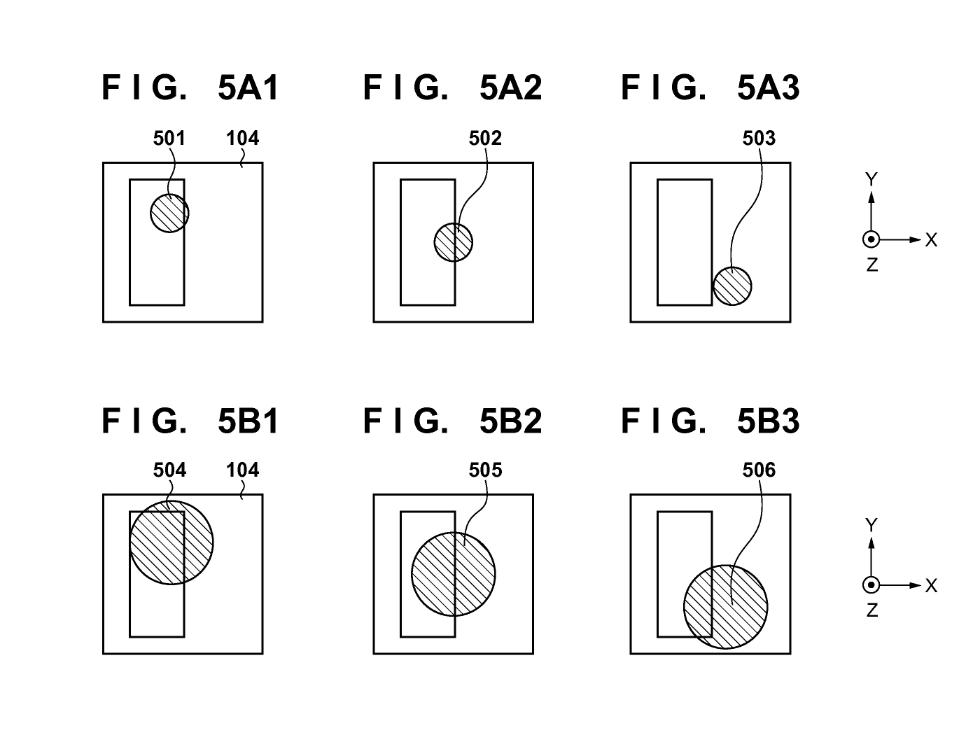

FIGS. 5A1 to 5A3 schematically show pupil images 501 to 503 (corresponding to an f-number of 5.6) formed on a plane of the shielding portion 104. The pupil image 501 (FIG. 5A1) is not shielded by the shielding portion 104 and mostly located in the opening in the shielding portion 104. The center of the pupil image 502 (FIG. 5A2) is located between the shielding portion 104 and the opening in the shielding portion 104. The pupil image 502 is formed at a position suitable for focus detection using the phase-difference detection method. The pupil image 503 (FIG. 5A3) is formed on the shielding portion 104 and entirely shielded against light. Like FIGS. 5A1 to 5A3, FIGS. 5B1 to 5B3 schematically show pupil images 504 to 506 (corresponding to an f-number of 1.2) formed on a plane of the shielding portion 104.

When a pupil image is small, the influence of the positional shift of the pupil image on focus detection accuracy is larger than when a pupil image is large, as exemplified by FIGS. 5A1 to 5A3. With the pupil images 501 to 503 shown in FIGS. 5A1 to 5A3, it is difficult to perform focus detection. In contrast to this, when a pupil image is large, the influence of the positional shift of the pupil image is smaller than when a pupil image is small, as exemplified by FIGS. 5B1 to 5B3. Therefore, focus detection accuracy is maintained at the pixel P_{AF}′ for focus detection. However, at the pixel P_{IM}′ for imaging, the shielding portion 204 causes vignetting and can lead to a deterioration in imaging performance, as indicated by the pupil image 411 shown in FIG. 4A2.

That is, as a result of selecting a microlens suitable for imaging, a pupil image becomes smaller than necessary at the pixel P_{AF}′ for focus detection, and the focus detection accuracy deteriorates. In contrast to this, as a result of selecting a microlens suitable for focus detection, a pupil image becomes larger than necessary, and the imaging performance deteriorates because of vignetting. In addition, in the use of a camera with interchangeable lenses, since lens changing will change the position of a pupil image, the influence of the positional change is large especially when the pupil image is small.

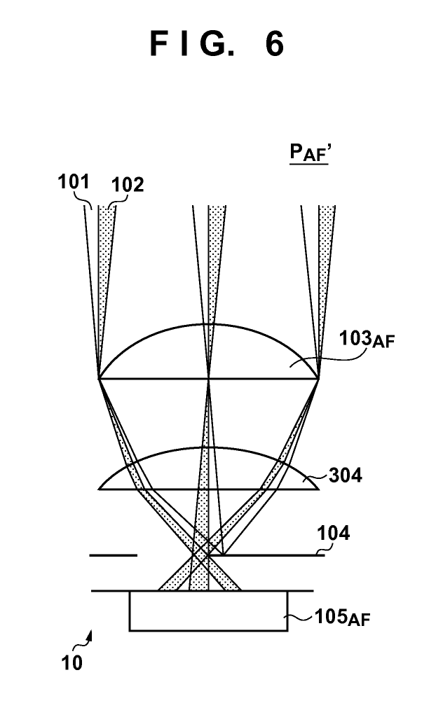

With regard to the influence described above, as especially exemplified by FIG. 6, when each microlens 103 has the same refractive index and shape and the pixel P_{AF} for focus detection is provided with an inner lens 304, since a pupil image becomes small, the focus detection accuracy tends to deteriorate. In addition, when the pixel P_{AF}′ for focus detection is provided with a microlens different from that of the pixel P_{IM}′ for imaging, only a pupil image at the pixel P_{AF}′ for focus detection differs in size.

### Second Reference Example

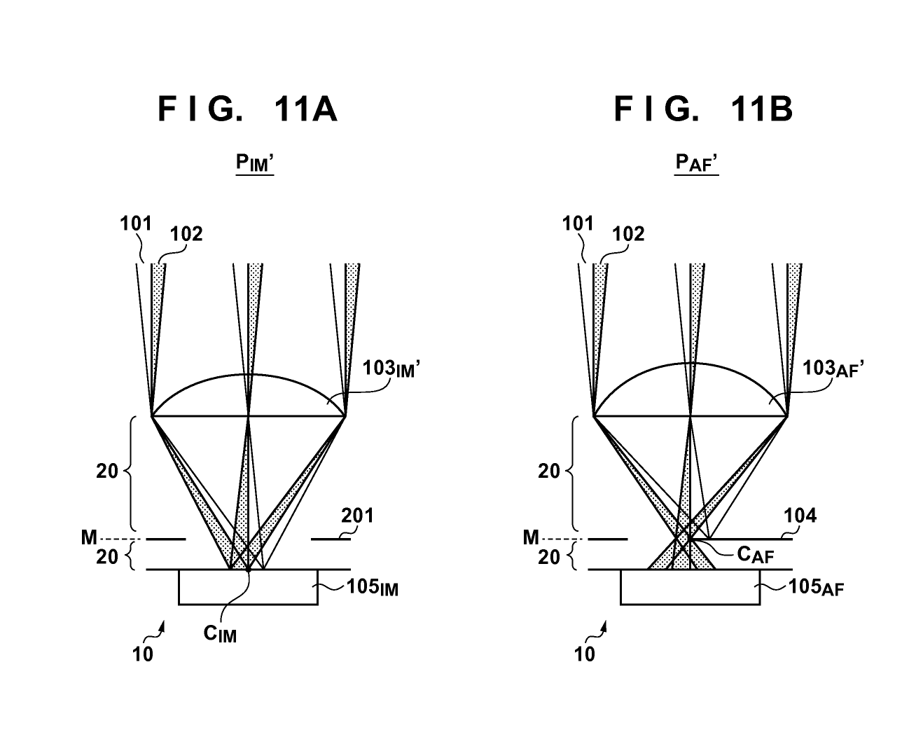

The structures of a pixel for imaging and a pixel for focus detection will be described as the second reference example with reference to FIGS. 11A to 16. FIGS. 11A and 11B schematically show the sectional structures of a pixel P_{IM}′ for imaging and a pixel P_{AF}′ for focus detection according to this reference example, respectively. The pixel P_{IM}′ for imaging includes a photoelectric conversion portion 105_{IM} provided on a semiconductor substrate 10 (to be referred to as the substrate 10 hereinafter) and a microlens 103_{IM}′ provided above the photoelectric conversion portion 105_{IM} (FIG. 11A). In addition, the pixel P_{AF}′ for focus detection can include a photoelectric conversion portion 105_{AF} provided on the substrate 10 and a microlens 103_{AF}′ of the photoelectric conversion portion 105_{AF} (FIG. 11B). Microlenses 103′ (103_{IM}′ and 103_{AF}′) have different lens powers and also have different shapes or different refractive indices. More specifically, these microlenses are formed to have different curvatures (heights). In this case, the “different shapes” means that the microlenses differ in at least height or bottom surface.

The member 20 is arranged between a photoelectric conversion portions 105 (105_{IM} and 105_{AF}) and a microlens 103′. In addition, an interconnection layer M is arranged in part of the region between the photoelectric conversion portions 105 and the microlens 103′. For example, an interconnection portion 201 is arranged on the interconnection layer M of the pixel P_{IM}′ for imaging. An interconnection portion for signal or power supply is used as the interconnection portion 201 to prevent color mixture with adjacent pixels. The interconnection portion 201 has a first opening. For example, the shielding portion 104 is arranged on the interconnection layer M of the pixel P_{AF}′ for focus detection. The shielding portion 104 has a second opening (smaller than the first opening) to perform phase-difference detection.

A light beam 101 is a light beam (to be referred to as the left light beam 101 hereinafter) from one (for example, the left half) of the regions obtained by dividing the pupil of an external imaging lens which forms an image of an object on a pixel array 1701. Likewise, a light beam 102 is a light beam (to be referred to as the right light beam 102 hereinafter) from the other (for example, the right half) of the regions obtained by dividing the pupil of the external imaging lens. Although the left light beam 101 and the right light beam 102 are exemplified in this case, the same applies to a case in which they are read as an upper light beam and a lower light beam, respectively.

In this case, the pixel P_{AF}′ for focus detection is configured such that the position C_{AF} at which a pupil image of the external imaging lens is formed (to be referred to as the image forming position C_{AF} hereinafter) is located at the shielding portion 104 or its neighboring place (first position). In addition, the pixel P_{IM}′ for imaging is configured such that the position C_{IM} at which a pupil image of the external imaging lens is formed (to be referred to as the image forming position C_{IM} hereinafter) is located nearer to the photoelectric conversion portion 105_{IM} (substrate 10) than the image forming position C_{AF} (second position). In this reference example, as described above, the microlens 103_{IM}′ and the microlens 103_{AF}′ are formed to have different curvatures (heights), and the image forming positions C (C_{IM} and C_{AF}) between the respective pixels are adjusted to desired positions.

With this arrangement, in the pixel P_{AF}′ for focus detection, the microlens 103_{AF}′ focuses the left light beam 101 and the right light beam 102 at (near) the shielding portion 104. In this case, the shielding portion 104 has an opening eccentrically positioned to one side (left side) relative to the center of the pixel P_{AF}′ for focus detection. The shielding portion 104 shields against the left light beam 101 of the left light beam 101 and the right light beam 102, and the right light beam 102 enters the photoelectric conversion portion 105_{AF}. Note that in another pixel for focus detection different from the pixel P_{AF}′ for focus detection, the shielding portion 104 has an opening eccentrically positioned to the other side (right side) relative to the center of the other pixel for focus detection. The left light beam 101 enters the photoelectric conversion portion 105_{AF}. The apparatus obtains the signals based on the right light beam 102 and the left light beam 101 from the two different pixels for focus detection in this manner, and properly performs focus detection based on the phase-difference detection method by using the signals.

On the other hand, the microlens 103 focuses the left light beam 101 and the right light beam 102 at (near) the photoelectric conversion portion 105_{IM}. This can improve the imaging performance of the solid-state imaging apparatus.

Pads, bonding wires, and the like, for power supply from the outside and signal exchange with the outside are arranged in the peripheral region of the pixel array 1701. Light reflected by these pads, and the like, becomes stray light, and may enter the pixel array 1701.

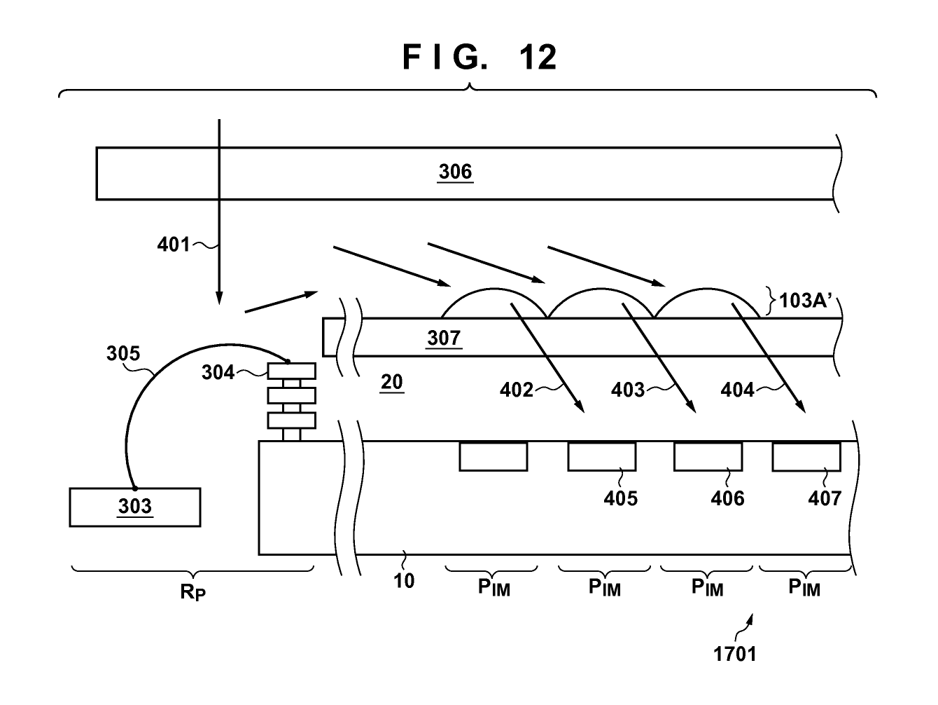

FIG. 12 schematically shows a region, of the sectional structure of the solid-state imaging apparatus I, which includes an end portion of the pixel array 1701. As exemplified by FIG. 12, the solid-state imaging apparatus I can receive power from the outside or exchange signals with the outside by connecting, for example, a pad 304 to an electrode 303 via a bonding wire 305. A transmissive protective plate member 306 (for example, a glass member) can be arranged on a microlens array 103A′ (the light incident side). A region R_{P} is an outside region of the pixel array 1701. The electrode 303, the pad 304, the bonding wire 305, and the like, can be arranged in the region R_{P}.

Of light 401 entering the region R_{P} through the protective plate member 306, the light reflected by the electrode 303, the pad 304, or the bonding wire 305 is reflected by the protective plate member 306, as indicated by the arrows in FIG. 12. The light reflected by the protective plate member 306 enters, as oblique incident light, the effective pixel region of the pixel array 1701, and then becomes leakage light to, for example, an adjacent pixel. As shown in FIG. 12, light 402, light 403, and light 404 cause color mixture between adjacent pixels. This phenomenon can become more conspicuous with oblique incident light which has entered at a relatively large incident angle.

Assume that only pixels for imaging are arranged in a pixel array (when no pixels for focus detection are provided). In this case, even if light leaks to adjacent pixels, any specific change does not easily occur in the amount of leakage light. Therefore, some signals of the image data obtained from the pixel array do not easily exhibit specific values. That is, the influences of the light 402, the light 403, and the light 404 on outputs (signal values) from photoelectric conversion portions 405 to 407 are continuous, and oblique incident light can appear as simple flare light in image data. However, when pixels for imaging and pixels for focus detection are mixed and arranged in a pixel array, pixel signals from the pixels for imaging sometimes exhibit specific values.

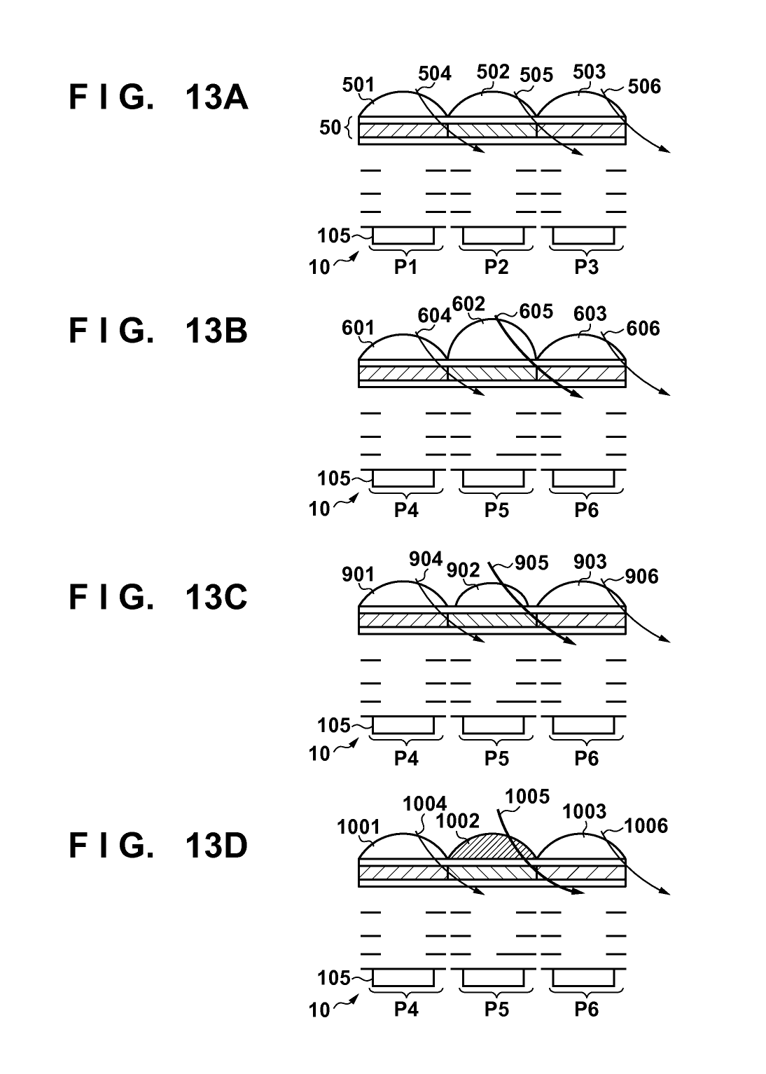

FIG. 13A schematically shows the sectional structure of a portion, of the pixel array 1701, in which pixels P1 to P3 for imaging are arranged, and how oblique incident light in the sectional structure becomes leakage light to adjacent pixels. Color filters layers 50 can be provided below microlenses 501 to 503 of the pixels P1 to P3 for imaging. FIG. 13A shows light 504 entering the microlens 501, light 505 entering the microlens 502, and light 506 entering the microlens 503. As described above, the influences of light on an output are continuous, and hence a specific output change does not easily occur.

FIG. 13B schematically shows the sectional structure of a portion in which a pixel P5 for focus detection is arranged between two pixels P4 and P6 for imaging, and how oblique incident light in the sectional structure becomes leakage light to adjacent pixels. As described above, a microlens 602 of the pixel P5 for focus detection is formed to be higher than microlenses 601 and 603 of the two pixels P4 and P6 for imaging to locate an image forming position C at a desired position. As a result, of light 604 entering the microlens 601, light 605 entering the microlens 602, and light 606 entering the microlens 603, the amount of light 605 is specifically large. For this reason, a pixel signal from the pixel P6 for imaging shown on the right side of FIG. 13B exhibits a specifically large value.

Note that a similar phenomenon occurs in an arrangement in which the microlenses of the two pixels P4 and P6 for imaging differ in lens shape or refractive index from the microlens of the pixel P5 for focus detection. For example, as shown in FIG. 13C, a similar phenomenon can occur in an arrangement in which microlenses 901 and 903 differ in diameter from a microlens 902 although they have the same height. In addition, for example, as shown FIG. 13D, a similar phenomenon can occur in an arrangement in which microlenses 1001 and 1003 differ in refractive index from a microlens 1002 although they have the same height and diameter.

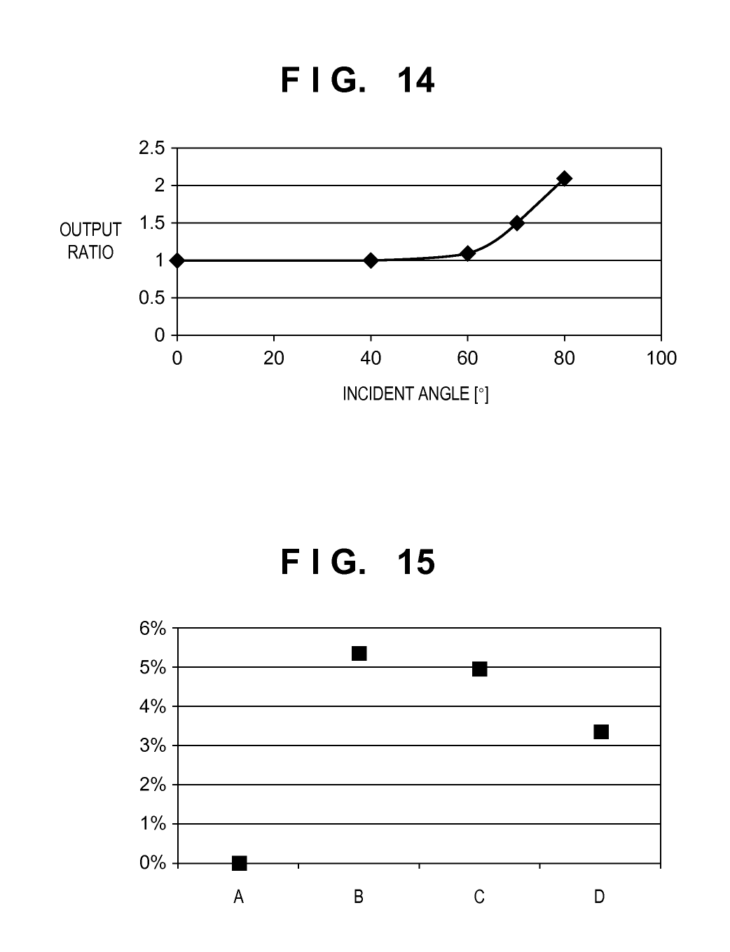

FIG. 14 shows the incident angle dependence of the ratio between signal values from a pixel for imaging, which is adjacent to a pixel for focus detection, and a pixel for imaging, which is not adjacent to the pixel for focus detection. Note that FIG. 14 shows the optical simulation result based on the finite-difference time-domain method (FDTD method). Simulation conditions were set such that the pixel pitch=4 μm, height of microlens of pixel for focus detection=1.5 μm, height of microlens of pixel for imaging=1.2 μm, and refractive index n of each microlens=1.6. As is obvious from the simulation result, the above signal value ratio becomes larger than 1 at an incident angle of 60° or more under the above simulation conditions. That is, at an incident angle of 60° or more, the influence of leakage light from a pixel for focus detection on a pixel for imaging becomes large.

FIG. 15 shows the amounts of change in the amount of leakage light to adjacent pixels at an incident angle of 70° depending on lens structures, with a pixel for imaging having a lens of lens type A. The following will describe a case in which a pixel for focus detection has a lens of lens type A, while a pixel for imaging has a lens of lens type A, and a case in which each pixel for imaging has one of lenses of lens types B to D, which differ in shape and refractive index from lens type A. FIG. 15 is a graph plotting the amounts of change (%) in the amount of leakage light in a case in which, while the amount of leakage light obtained when the lens of the pixel for focus detection is of type A is set as a reference, the lenses of the remaining pixels are of types B to D. A microlens of lens type A has a height of 1.2 μm and a radius of 2.3 μm, with refractive index n of constituent material=1.6. Lens type B has a height of 1.3 μm, which differs from lens type A (see FIG. 13B). Lens type C has a radius of 2.2 μm, which differs from lens type A (see FIG. 13C). Lens type D has refractive index n of constituent material=2.0, which differs from type A (see FIG. 13D). As is obvious from this plotted result, the amounts of leakage light to the adjacent pixels with lens types B to D are larger than that with lens type A.

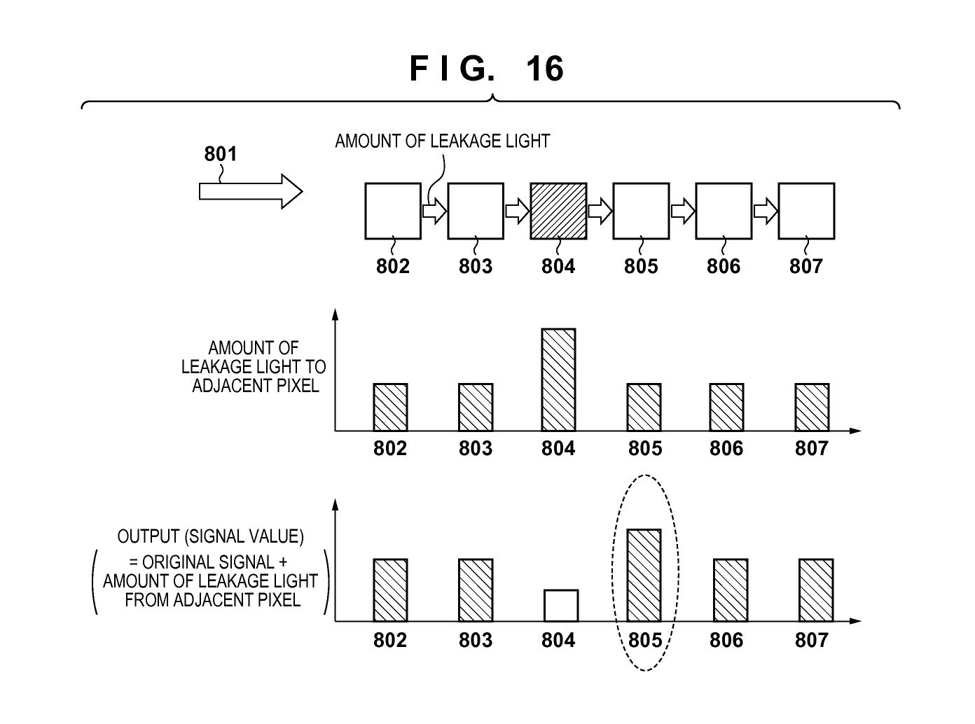

FIG. 16 shows the amounts of leakage light to pixels 802 to 807 as adjacent pixels and signal values from the pixels 802 to 807 when oblique incident light 801 enters in the direction indicated by the arrow. Of the pixels 802 to 807, the pixel 804 is a pixel for focus detection, and the remaining pixels are pixels for imaging. The amount of leakage light from the pixel 804 for focus detection to the adjacent pixel is larger than the amounts of leakage light from the remaining pixels to the adjacent pixels. As a consequence, a signal value from the pixel 805 for imaging, of the pixels 802 to 807, becomes specifically large, because of leakage light from the pixel 804 for focus detection, resulting in aliasing.

As described above, since a signal from a pixel for imaging adjacent to a pixel for focus detection can have a specifically large value, for example, a patchy pattern corresponding to the arrangement of pixels for focus detection is formed in the image data obtained from the solid-state imaging apparatus.

In addition, although it is conceivable to use a method of performing correction processing and interpolation processing for image data, since light does not always leak to adjacent pixels, it is difficult to perform uniform processing.

### First Embodiment

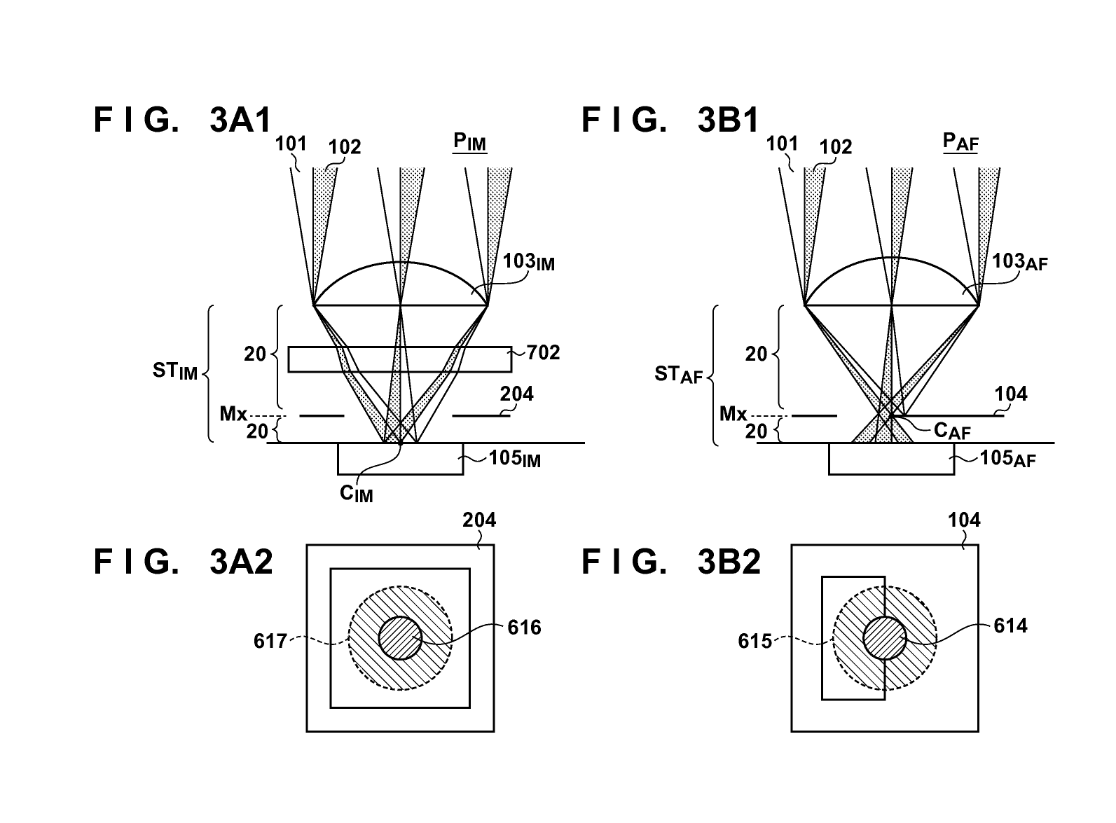

FIG. 3A1 schematically shows the sectional structure of a pixel P_{IM} for imaging. The pixel P_{IM} for imaging includes a photoelectric conversion portion 105_{IM} provided on a semiconductor substrate 10 (to be referred to as the substrate 10 hereinafter), a structure ST_{IM} provided on the substrate 10, and a microlens 103_{IM} provided on the structure ST_{IM}. In addition, FIG. 3B1 schematically shows the sectional structure of a pixel P_{AF} for focus detection. The pixel P_{AF} for focus detection includes a photoelectric conversion portion 105_{AF} provided on the substrate 10, a structure ST_{AF} provided on the substrate 10, and a microlens 103_{AF} provided on the structure ST_{AF}.

A structure ST (ST_{IM} and ST_{AF}) includes a member 20 and at least one interconnection layer Mx provided in the member 20. For example, the structure ST includes a plurality of interlayer dielectric films each formed from an member (silicon oxide or the like) and at least one interconnection layer formed from a metal (copper, aluminum, or the like) and arranged between the interlayer dielectric films. For example, the member 20 includes the first insulating layer formed under the interconnection layer Mx and the second insulating layer formed on the interconnection layer Mx.

On the interconnection layer Mx, the structure ST_{IM} in the pixel P_{IM} for imaging includes, for example, a shielding portion 204, and the structure ST_{AF} in the pixel P_{AF} for focus detection includes, for example, a shielding portion 104. The interconnection layer Mx on which the shielding portion 104 and the shielding portion 204 are arranged may be the first interconnection layer nearest to the substrate 10 or the second interconnection layer arranged above the first interconnection layer.

In addition, the microlens 103_{IM} of the pixel P_{IM} for imaging and the microlens 103_{AF} of the pixel P_{AF} for focus detection have the same lens power. More specifically, microlens 103 (103_{IM} and 103_{AF}) are formed from a single member and have the same shape. That is, the respective microlens 103 (103_{IM} and 103_{AF}) are formed to have the same shape and refractive index.

A light beam 101 is a light beam (to be referred to as the left light beam 101 hereinafter) from one (for example, the left half) of the regions obtained by dividing the pupil of an external imaging lens formed on a pixel array 801 of an object into halves. Likewise, a light beam 102 is a light beam (to be referred to as the right light beam 102 hereinafter) from the other (for example, the right half) of the regions obtained by dividing the pupil of the external imaging lens into halves. Although the left light beam 101 and the right light beam 102 are exemplified in this case, the same applies to a case in which they are read as an upper light beam and a lower light beam, respectively.

In this case, in the pixel P_{AF} for focus detection, the structure ST_{AF} and the microlens 103_{AF} are provided such that an image forming position C_{AF} of a pupil image of the external imaging lens is located on the interconnection layer Mx or near it. In addition, in the pixel P_{IM} for imaging, the structure ST_{IM} and the microlens 103_{IM} are provided such that an image forming position C_{IM} of a pupil image of the external imaging lens is located on a side (substrate 10 side) nearer to the photoelectric conversion portion 105_{IM} than the image forming position C_{AF}. In this embodiment, the member 20 in the structure ST_{IM} of the pixel P_{IM} for imaging has a flat plate-like member above the interconnection layer Mx. Assume that the member 20 has a parallel plate member 702 as this flat plate-like member. The parallel plate member 702 is formed from a member (silicon nitride or the like) having a higher refractive index than the surrounding interlayer dielectric films. With this arrangement, image forming positions (C_{IM} and C_{AF}) between the respective pixels are adjusted to desired positions.

The image forming position C_{AF} in the pixel P_{AF} for focus detection is located on the interconnection layer Mx, as exemplified by FIG. 3B1, and the microlens 103_{AF} focuses the left light beam 101 and the right light beam 102 at (near) the shielding portion 104. In this case, the shielding portion 104 has an opening eccentrically positioned to one side (left side) relative to the center of the pixel P_{AF} for focus detection. The shielding portion 104 shields against the left light beam 101 of the left light beam 101 and the right light beam 102, and the right light beam 102 enters the photoelectric conversion portion 105_{AF}. Note that in another pixel of focus detection (for example, a pixel P_{AF}2 for focus detection), the shielding portion 104 has an opening eccentrically positioned to the other side (right side) relative to the center of the pixel P_{AF}2 for focus detection. The left light beam 101 enters the photoelectric conversion portion 105_{AF}. The apparatus properly performs focus detection based on the phase-difference detection method by using the signal obtained from the right light beam 102 by the pixel P_{AF} for focus detection and the signal obtained from the left light beam 101 by the pixel P_{AF}2 for focus detection in this manner.

On the other hand, the image forming position C_{IM} in the pixel P_{IM} for imaging is located on the surface of the substrate 10, as exemplified by FIG. 3A1, and the microlens 103 focuses the left light beam 101 and the right light beam 102 at (near) the photoelectric conversion portion 105_{IM}. This can improve the imaging performance of the solid-state imaging apparatus.

Compared with the first reference example described above, this embodiment uses the parallel plate member 702 instead of the method of providing the microlens 103_{AF}′ having a large lens power only for the pixel P_{AF}′ for focus detection or the method of providing the inner lens 304 having a lens power in addition to the microlens. This suppresses a difference in pupil image magnification between the pixel P_{IM} for imaging and the pixel P_{AF} for focus detection.

FIG. 3A2 schematically shows the sectional structure of the pixel P_{IM} for imaging on a plane of the interconnection layer Mx. More specifically, FIG. 3A2 schematically shows the shielding portion 204 and the pupil image formed on a plane of the interconnection layer Mx by the pupil of the external imaging lens. FIG. 3B2 schematically shows the sectional structure of the pixel P_{AF} for focus detection on a plane of the interconnection layer Mx. More specifically, FIG. 3B2 schematically shows the shielding portion 104 and the pupil image formed on a plane of the interconnection layer Mx by the microlens 103. Since this embodiment uses the parallel plate member 702, the pixel P_{IM} for imaging is equal in image magnification to the pixel P_{AF} for focus detection. For example, a pupil image 617 and a pupil image 615 (both corresponding to, for example, an f-number of 1.2) are those formed at the same magnification. In addition, for example, a pupil image 616 and a pupil image 614 (both corresponding to, for example, an f-number of 5.6) are those formed at the same magnification. Therefore, the arrangement of this embodiment suppresses a deterioration in imaging accuracy or focus detection accuracy described in the first reference example, and is also advantageous in improving the focus detection accuracy while maintaining the imaging performance.

As described above, the structure ST (ST_{IM} and ST_{AF}) includes, for example, a plurality of interlayer dielectric films (including first and second insulating layers) and at least one interconnection layer arranged between the interlayer dielectric films. The parallel plate member 702 is formed on at least the second insulating layer of the first and second insulating layers.

The solid-state imaging apparatus I including the pixels P_{IM} for imaging and the pixels P_{AF} for focus detection is manufactured by using a known semiconductor manufacturing process. For example, first of all, a plurality of photoelectric conversion portions 105 are formed on the substrate 10, and the above structures ST are formed on the substrate 10 (first step). In this step, a parallel plate member is formed in the member 20 above the interconnection layer Mx in the structure ST_{IM} of the pixel P_{IM} for imaging so as to locate an image forming position C of a pupil image at a desired position. It is possible to implement this step by forming an opening by etching a region of the pixel P_{IM} for imaging after depositing the above second insulating layer (for example, the insulating layer on the first interconnection layer corresponding to the interconnection layer Mx), and then filling the opening with a high refractive index member. Thereafter, planarization processing or the like is performed to provide the parallel plate member 702 described above. Subsequently, the second and third insulating layers, and the like, are formed to complete the structure ST, and a microlens array is formed on the structure ST in correspondence with each photoelectric conversion portions 105 (second step).

The position and shape of the parallel plate member 702, that is, the flat plate-like member, are not limited to those in this embodiment as long as it is possible to adjust the image forming position C of a pupil image to a desired position. An antireflection structure may be provided at the interface between the dielectric interlayer and the parallel plate member 702 so as to suppress reflection and interference of light caused at the interface.

This embodiment has exemplified, as a flat plate-like member, the parallel plate member whose upper and lower surfaces are parallel to the surface of the semiconductor substrate. However, the flat plate-like member is only required to exhibit changes in refractive index in a direction perpendicular to the surface of the substrate 10. Assume that in the member 20, the insulating layer is made of silicon oxide and the flat plate-like member is made of silicon nitride. In this case, the member 20 may have an arrangement in which the composition gradually changes from silicon oxide to silicon nitride, starting from the boundary between the insulating layer and the flat plate-like member. In addition, it is possible to use a flat plate-like member having an opening only in a portion corresponding to a pixel for imaging, which can also serve as an insulating layer. In addition, the upper and lower surfaces of the flat plate-like member may not be parallel to the surface of the semiconductor substrate, and at least one of the upper and lower surfaces of the flat plate-like member may have an inclination relative to the surface of the semiconductor substrate. That is, the flat plate-like member has an arrangement substantially having no curved surface at a portion serving as an optical path.

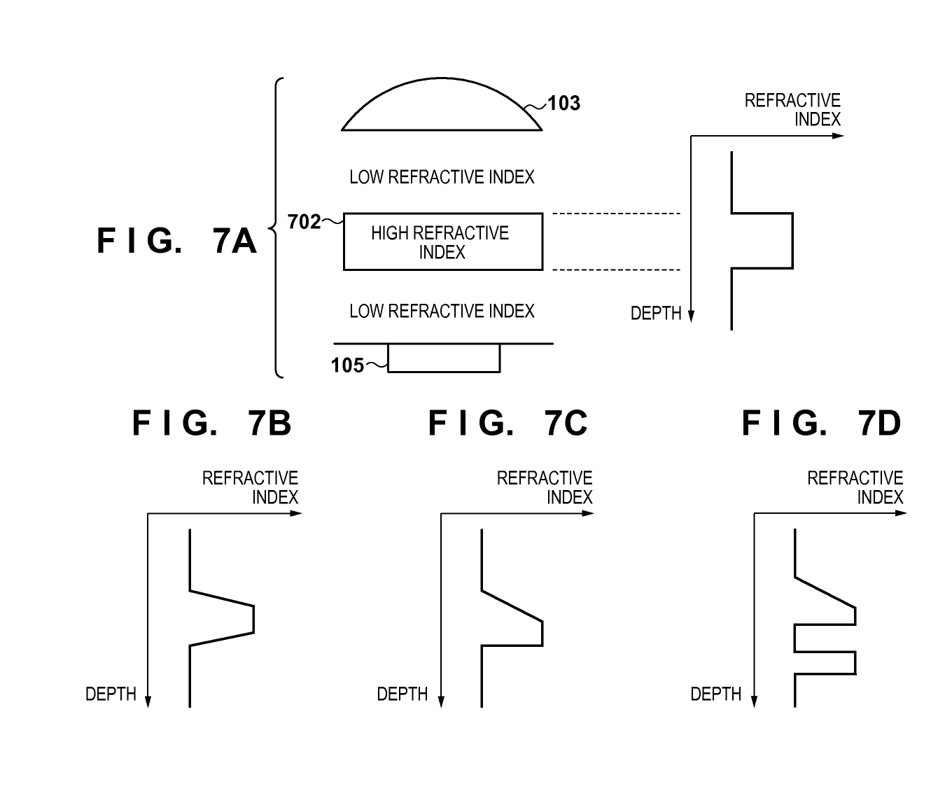

In addition, in the pixel P_{AF} for focus detection, the image forming position C_{AF} is adjusted to be located at the interconnection layer Mx or its neighboring place. In the pixel P_{IM} for imaging, the image forming position C_{IM} is adjusted to be located nearer to the photoelectric conversion portion 105_{IM} than the image forming position C_{AF} of the pupil image. Therefore, the members 20 are provided such that the average refractive index of the member 20 of the pixel P_{IM} for imaging becomes higher than that of the member 20 of the pixel P_{AF} for focus detection. This embodiment has exemplified the arrangement having the parallel plate member 702 provided on one of the insulating layers above the interconnection layer Mx. FIG. 7A shows the refractive index distribution of the member 20 in a direction perpendicular to the surface of the substrate 10 in this arrangement. In the arrangement, the refractive index distribution of the member 20 including the parallel plate member 702 exhibits that the refractive index discontinuously increases at a boundary with the parallel plate member 702 and discontinuously decreases at a boundary with the parallel plate member 702 in the depth direction. However, the present invention is not limited to the arrangement. For example, as exemplified by FIG. 7B, the refractive index distribution of the member 20 including the parallel plate member 702 exhibits that the refractive index continuously increases at a boundary with the parallel plate member 702 and continuously decreases at a boundary with the parallel plate member 702 in the depth direction. That is, as exemplified by FIGS. 7A to 7D, the member 20 may be provided so as to satisfy at least one of a condition including one or more discontinuous increases or decreases and a condition including one or more continuous increases or decreases.

As described above, this embodiment can reduce errors (for example, alignment errors and shape errors) caused by manufacturing variations, and hence is advantageous in terms of the manufacture. In addition, the embodiment can uniformly form a microlens array, and hence is further advantageous in terms of the manufacture. Furthermore, the embodiment is configured such that the magnification of the pixel P_{IM} for imaging is the same as that of the pixel P_{AF} for focus detection, and hence is advantageous in improving focus detection accuracy while maintaining imaging performance.

### Second Embodiment

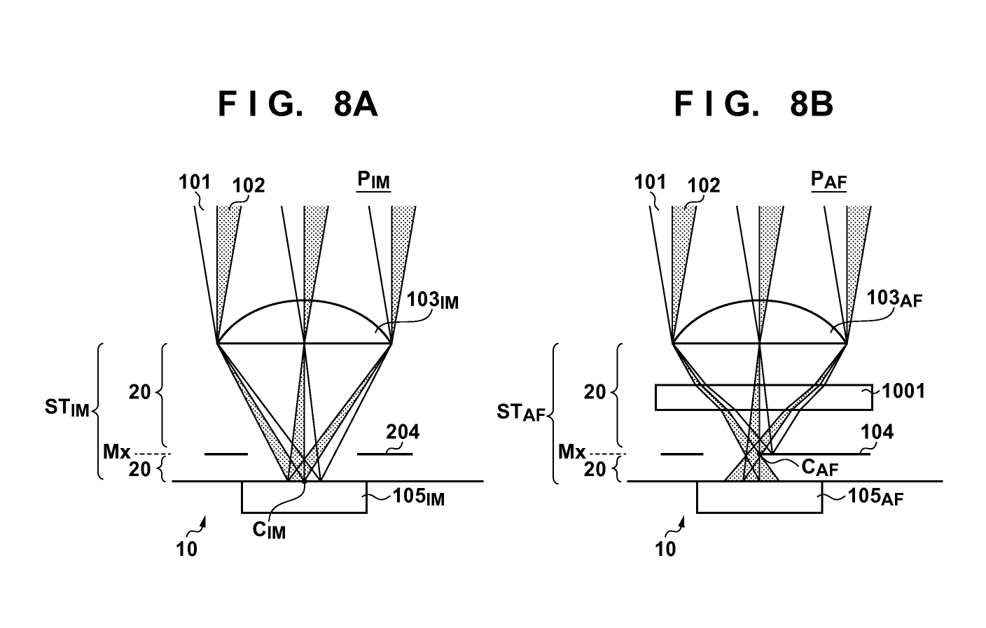

In the first embodiment described above, the parallel plate member 702 formed from a high refractive index member is provided for the member 20 of the structure ST_{IM} in the pixel P_{IM} for imaging so as to locate the image forming position C (C_{IM} and C_{AF}) of a pupil image at a desired position. The second embodiment differs in arrangement from the first embodiment in that a parallel plate member 1001 formed from a low refractive index member is provided for an member 20 of a structure ST_{AF} in a pixel P_{AF} for focus detection. FIGS. 8A and 8B schematically show the sectional structures of a pixel P_{IM} for imaging and the pixel P_{AF} for focus detection according to this embodiment, respectively.

The parallel plate member 1001 in this embodiment is formed from a member (for example, a fluoride-containing resin) having a lower refractive index than the surrounding member 20. The parallel plate member 1001 may have, for example, a porous structure to effectively achieve a reduction in refractive index. With this arrangement, in the pixel P_{AF} for focus detection, the image forming position C_{AF} of a pupil image is located at an interconnection layer Mx or its neighboring place, whereas in the pixel P_{IM} for imaging, an image forming position C_{IM} of a pupil image is located on a side (substrate 10 side) nearer to a photoelectric conversion portion 105_{IM} than an image forming position C_{AF} of a pupil image.

This embodiment can obtain the same effects as those of the first embodiment. In addition, the second embodiment can reduce the curvatures (heights) of microlenses 103_{IM} and 103_{AF} as compared with those in the arrangement of the first embodiment, and hence is more advantageous in terms of the manufacture.

### Third Embodiment

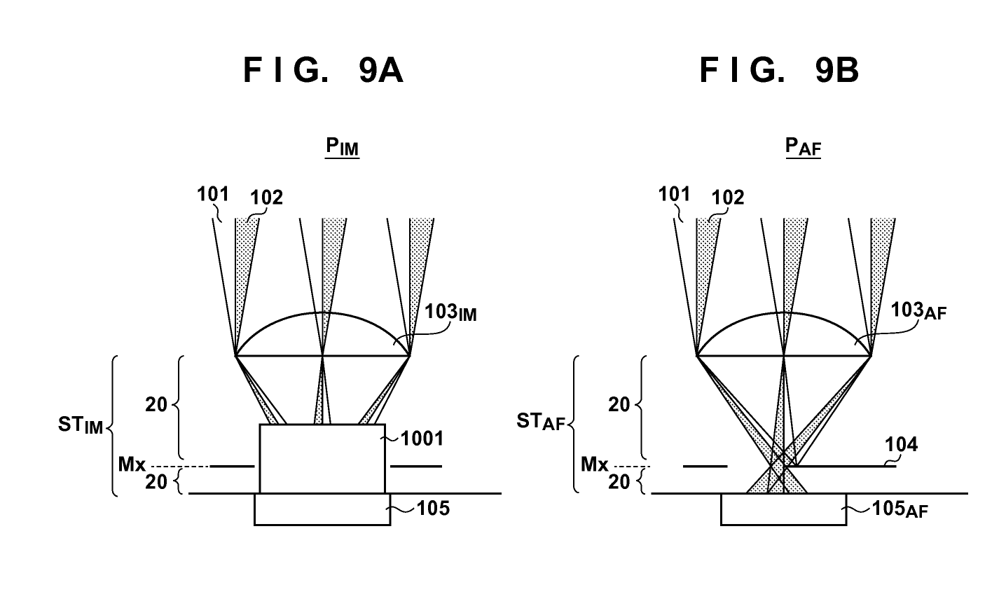

The first and second embodiments each have exemplified the arrangement having the parallel plate member 702 or 1001 provided above the interconnection layer Mx in the member 20 of the pixel P_{IM} for imaging or the pixel P_{AF} for focus detection. However, a parallel plate member may also be provided below an interconnection layer Mx as long as a parallel plate member is provided at least above the interconnection layer Mx, as in the third embodiment. FIGS. 9A and 9B schematically show the sectional structures of a pixel P_{IM} for imaging and a pixel P_{AF} for focus detection according to this embodiment, respectively.

In this embodiment, in a structure S_{IM} of the pixel P_{IM} for imaging, a parallel plate member 1101 formed from a high refractive index member is provided from the upper surface of a substrate 10 to above the interconnection layer Mx. The parallel plate member 1101 is provided to have a width smaller than the opening formed in a shielding portion 204. In this case, since the parallel plate member 1101 also has a function as the light guide portion of an optical waveguide, it is only required to make a light beam passing through a microlens 103_{IM} properly enter the parallel plate member 1101.

According to this embodiment, the parallel plate member 1101 can obtain the same effects as those in the first embodiment while having a function as a light guide portion. In addition, according to the embodiment, it is only required to make a light beam passing through the microlens 103_{IM} properly enter the parallel plate member 1101. Therefore, it is possible to decide design values for the microlens 103_{IM} and a microlens 103_{AF} in accordance with the specifications of the pixel P_{AF} for focus detection. This is advantageous in terms of design.

### Fourth Embodiment

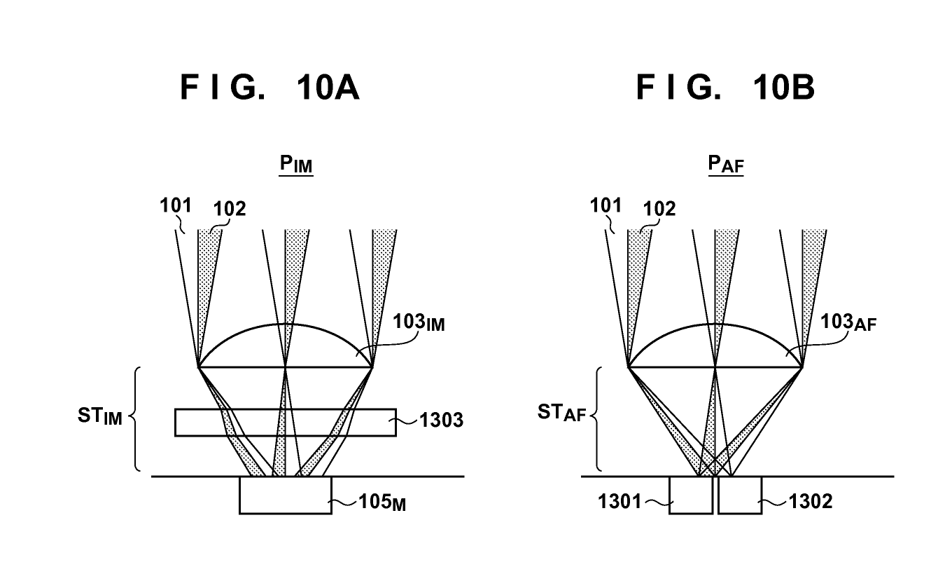

The first to third embodiments each have exemplified the arrangement having the shielding portion 104 which limits incident light on the interconnection layer Mx of the structure ST_{AF} in the pixel P_{AF} for focus detection to perform focus detection processing based on the phase-difference detection method. However, it is possible to use an arrangement having a plurality of photoelectric conversion portions provided in correspondence with a plurality of portions of the pupil region of an imaging lens to perform focus detection based on the phase-difference detection method using the signals obtained from the respective photoelectric conversion portions. For example, the fourth embodiment uses an arrangement in which a pixel P_{AF} for focus detection includes two photoelectric conversion portions to perform focus detection by using the signals obtained from the two photoelectric conversion portions. FIGS. 10A and 10B schematically show the sectional structures of a pixel P_{IM} for imaging and the pixel P_{AF} for focus detection according to this embodiment, respectively.

In this embodiment, the pixel P_{AF} for focus detection includes a first photoelectric conversion portion 1301 and a second photoelectric conversion portion 1302 which are formed on a substrate. The pair of photoelectric conversion portions 1301 and 1302 are provided to focus one of a left light beam 101 and a right light beam 102 onto one of the photoelectric conversion portions 1301 and 1302 and focus the other light beam onto the other of the photoelectric conversion portions 1301 and 1302. As shown in FIG. 10B, the first photoelectric conversion portion 1301 receives the right light beam 102, and the second photoelectric conversion portion 1302 receives the left light beam 101. This arrangement is not limited to this embodiment. For example, the pair of photoelectric conversion portions 1301 and 1302 may be provided for the same pixel P_{AF} for focus detection or for two different pixels P_{AF} for focus detection. In addition, for example, the embodiment may use an arrangement having three or more photoelectric conversion portions provided for the same pixel P_{AF} for focus detection.

In this case, the pixel P_{IM} for imaging is provided with a parallel plate member 1303 as in the first embodiment. If microlenses 103_{AF} and 103_{IM} of the respective pixels are uniformly formed, the left light beam 101 and the right light beam 102 pass through the microlens 103_{IM} and are focused in a photoelectric conversion portion 105_{IM} in the pixel P_{IM} for imaging. According to this arrangement, it is possible to change the design to gradually change sensitivity with, for example, a change in f-number by adjusting an image forming position C_{IM} of a pupil image in the pixel P_{IM} for imaging.

As described above in each embodiment, an member 20 of at least one of the pixel P_{IM} for imaging and the pixel P_{AF} for focus detection has a parallel plate member 702 or the like above at least an interconnection layer Mx. The parallel plate member differs in refractive index from the surrounding member, and is provided to locate an image forming position C of a pupil image at a desired position in each of the pixel P_{IM} for imaging and the pixel P_{AF} for focus detection. More specifically, in the pixel P_{AF} for focus detection, an image forming position C_{AF} of a pupil image is adjusted at the interconnection layer Mx or its neighboring place (first position). In the pixel P_{IM} for imaging, the image forming position C_{IM} of a pupil image is adjusted to be located nearer to the photoelectric conversion portion 105_{IM} (second position) than the image forming position C_{AF} of the pupil image.

As described above, according to the present invention, the pixel P_{IM} for imaging and the pixel P_{AF} for focus detection are configured to have the same pupil image magnification. This suppresses a deterioration in imaging performance or focus detection performance and is advantageous in improving focus detection accuracy while maintaining image quality. In addition, the present invention can reduce errors (for example, alignment errors and shape errors) caused by manufacturing variations as compared with a case in which a plurality of lenses (microlenses and inner lenses) are separately formed for one pixel, and hence is advantageous in terms of the manufacture. Furthermore, the present invention can uniformly form a microlens array, and hence is further advantageous in terms of the manufacture.

Although the four embodiments including the first to fourth embodiments have been described above, the present invention is not limited to them. The objects, states, applications, functions, and other specifications of the present invention can be changed as needed, and other embodiments can implement the present invention.

### Fifth Embodiment

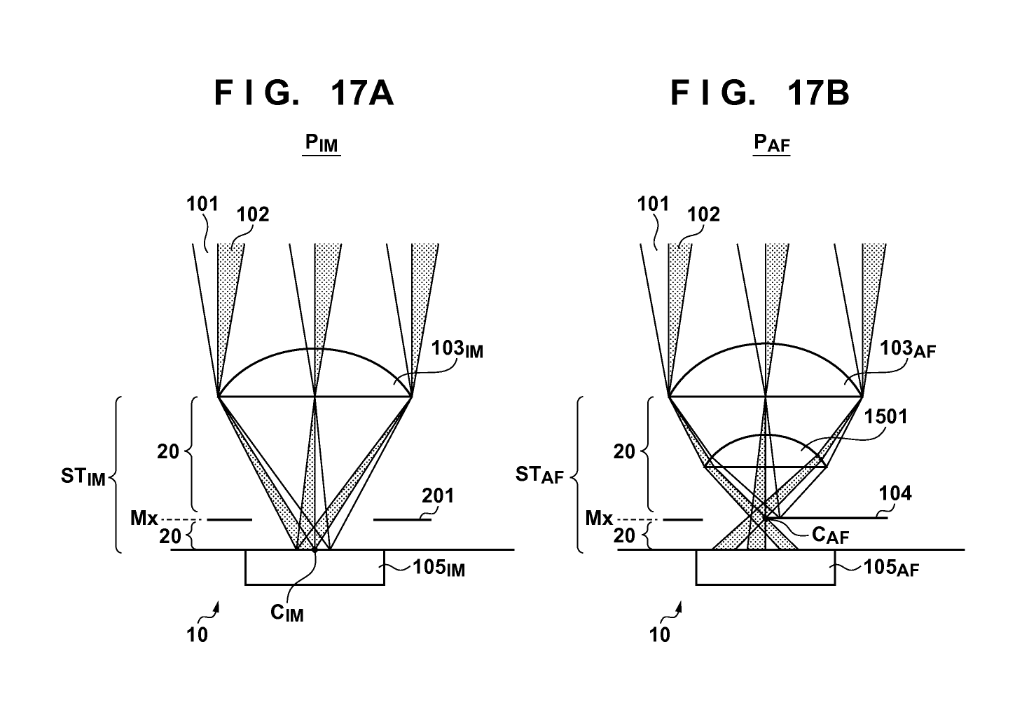

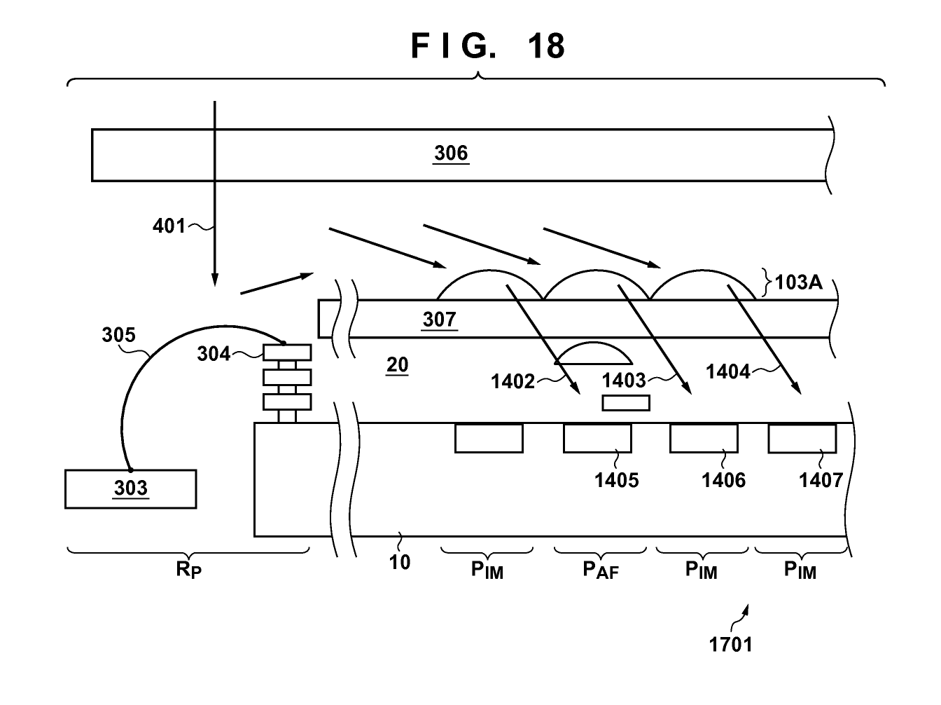

The fifth embodiment of the present invention will be described with reference to FIGS. 17A to 18. FIGS. 17A and 17B schematically show the sectional structures of a pixel P_{IM} for imaging and a pixel P_{AF} for focus detection according to this embodiment. The pixel P_{IM} for imaging includes a photoelectric conversion portion 105_{IM} provided on a substrate 10, a structure ST_{IM} provided on the substrate 10, and a microlens 103_{IM} provided on the structure ST_{IM}. The pixel P_{AF} for focus detection includes a photoelectric conversion portion 105_{AF} provided on the substrate 10, a structure ST_{AF} provided on the substrate 10, and a microlens 103_{AF} provided on the structure ST_{AF}.

A structure ST (structure ST_{IM} and structure ST_{AF}) includes a member 20 and at least one interconnection layer Mx provided in the member 20. For example, the structure ST includes a plurality of interlayer dielectric films each formed from a member (silicon oxide or the like) and at least one interconnection layer formed from a metal (copper, aluminum, or the like) and arranged between the interlayer dielectric films. For example, the member 20 includes the first insulating layer formed under the interconnection layer Mx and the second insulating layer formed on the interconnection layer Mx.

On the interconnection layer Mx, the structure ST_{IM} in the pixel P_{IM} for imaging includes, for example, an interconnection portion 201, and the structure ST_{AF} in the pixel P_{AF} for focus detection includes, for example, a shielding portion 104. The interconnection layer Mx on which the shielding portion 104 and the interconnection portion 201 are arranged may be the first interconnection layer nearest to the substrate 10 or the second interconnection layer arranged above the first interconnection layer.

In this case, the microlens 103_{IM} of the pixel P_{IM} for imaging and the microlens 103_{AF} of the pixel P_{AF} for focus detection have the same lens shape and refractive index. More specifically, for example, the microlenses 103 (103_{IM} and 103_{AF}) are made of the same material and have the same curvature (height and radius). In addition, in the pixel P_{AF} for focus detection, the insulating member 20 of the structure ST_{AF} includes an inner lens 1501. The inner lens 1501 is formed from a material (for example, silicon nitride) having a higher refractive index than the surrounding member. This locates an image forming position C_{AF} at (near) the shielding portion 104. Although the exemplified inner lens 1501 is formed into a convex shape by using a high refractive index member, the inner lens 1501 may be formed into a concave shape by using a low refractive index member. In addition, the image forming position C_{IM} is located at (near) the photoelectric conversion portion 105_{IM}. For example, the image forming position C_{AF} is nearer to the shielding portion 104 than the photoelectric conversion portion, and the image forming position C_{IM} is nearer to the photoelectric conversion portion 105_{IM} than the shielding portion 104.

With this arrangement, the pixel P_{IM} for imaging can focus a left light beam 101 and a right light beam 102 at (near) the photoelectric conversion portion 105_{IM}. On the other hand, the pixel P_{AF} for focus detection focuses the left light beam 101 and the right light beam 102 at (near) the photoelectric conversion portion 105_{IM}. Of these light beams, the left light beam 101 is shielded by the shielding portion 104, and the right light beam 102 enters the photoelectric conversion portion 105_{AF}.

Like FIG. 12 (of the second reference example), FIG. 18 schematically shows a region, of the sectional structure of the solid-state imaging apparatus I, which includes an end portion of a pixel array 1701 having the pixels P_{IM} for imaging and the pixel P_{AF} for focus detection according to this embodiment. The pixel in which a photoelectric conversion portion 1406 of photoelectric conversion portions 1405 to 1407 is arranged is a pixel for focus detection. As described above, the microlenses of a pixel for imaging and a pixel for focus detection have the same lens power, and it is possible to suppress a specific change in the amount of leakage light caused by oblique incident light entering a microlens array 103A in FIG. 18. That is, it is possible to suppress specific increases in the influences of leakage light 1402, leakage light 1403, and leakage light 1404 on outputs (signal values) from the photoelectric conversion portions 1405 to 1407.

According to the above arrangement, the pixel P_{IM} for imaging and the pixel P_{AF} for focus detection which are adjacent to each other are provided with the microlenses 103 having the same shape and refractive index, and it is possible to suppress a specific change in signal value from the pixel P_{IM} for imaging which can be caused by oblique incident light. Therefore, compared with the second reference example described above, this embodiment is advantageous in making the amount of leakage light uniform between a pixel for imaging and a pixel for focus detection which are adjacent to each other.

In the arrangement described above, in the pixel P_{IM} for imaging and the pixel P_{AF} for focus detection which are adjacent to each other, the microlenses 103 have the same shape and refractive index. However, the arrangement of this embodiment does not limit the spirit of the present invention as long as it is possible to suppress specific changes in signal value between adjacent pixels which are caused by the above leakage light. For example, the present invention can include an arrangement in which the respective microlenses in a peripheral region of the pixel array 1701 have the same lens shape and refractive index, and differ in lens shape and refractive index from the microlenses in a central region. That is, for example, a microlens array may be formed to have a lens curvature distribution corresponding to shading which can occur in image data.

### Sixth Embodiment

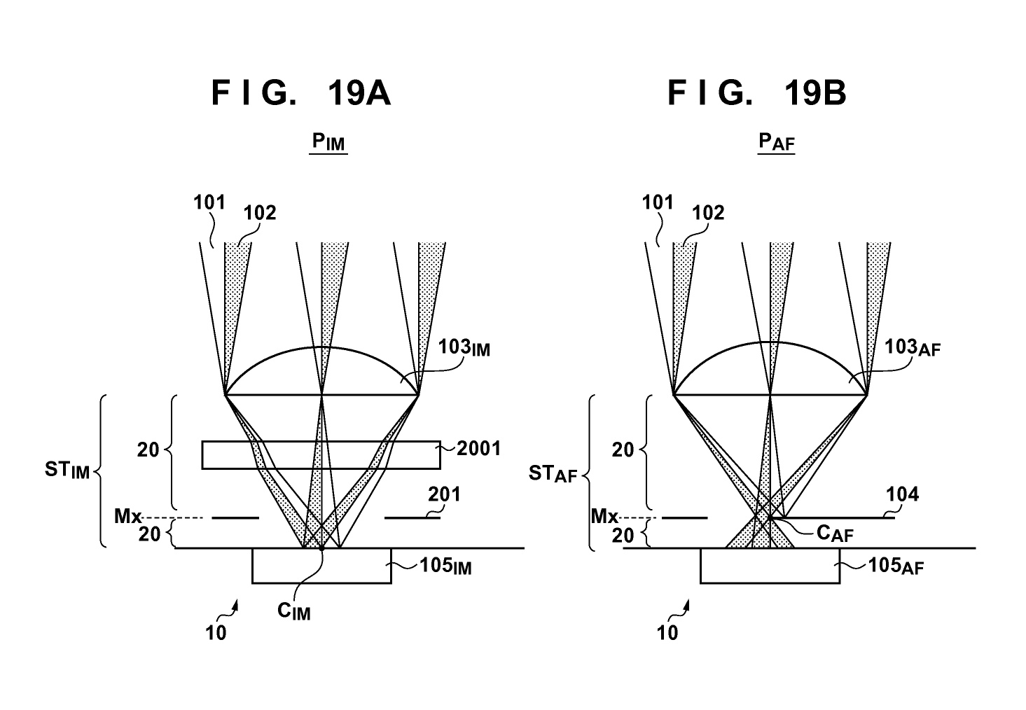

The fifth embodiment has exemplified the arrangement having the inner lens 1501 provided for the pixel P_{AF} for focus detection. However, the present invention is not limited to this arrangement. For example, the interface between two members having different refractive indices may be a planar shape, or parallel plate members having different refractive indices may be simply provided. FIGS. 19A and 19B schematically show the sectional structures of a pixel P_{AF} for focus detection and a pixel P_{IM} for imaging according to this embodiment.

In this embodiment, a member 20 in a structure ST_{IM} of the pixel P_{IM} for imaging includes a parallel plate member 2001 above an interconnection layer Mx. The parallel plate member 2001 can be formed from a member (silicon nitride or the like) having a higher refractive index than the surrounding member. This arrangement can adjust image forming positions C (image forming position C_{IM} and image forming position C_{AF}) between the respective pixels to desired positions.

The position and thickness of the parallel plate member 2001 are not limited to those in the arrangement according to this embodiment as long as it is possible to adjust the image forming position C to a desired position. In addition, when, for example, the parallel plate member 2001 is formed between interlayer dielectric films, an antireflection structure may be provided at the interface between the dielectric interlayer and the parallel plate member 2001 so as to suppress reflection and interference caused at the interface.

In addition, in the pixel P_{AF} for focus detection, the image forming position C_{AF} can be adjusted to be located at the interconnection layer Mx or its neighboring place. In the pixel P_{IM} for imaging, the image forming position C_{IM} can be adjusted to be located nearer to a photoelectric conversion portion 105_{IM} than the image forming position C_{AF}. This makes it possible to provide the member 20 such that the optical path length in the member 20 of the pixel P_{IM} for imaging becomes longer than that in the member 20 of the pixel P_{AF} for focus detection. In addition, the average refractive index of the member 20 of the pixel P_{IM} for imaging may be higher than the average refractive index of the member 20 of the pixel P_{AF} for focus detection.

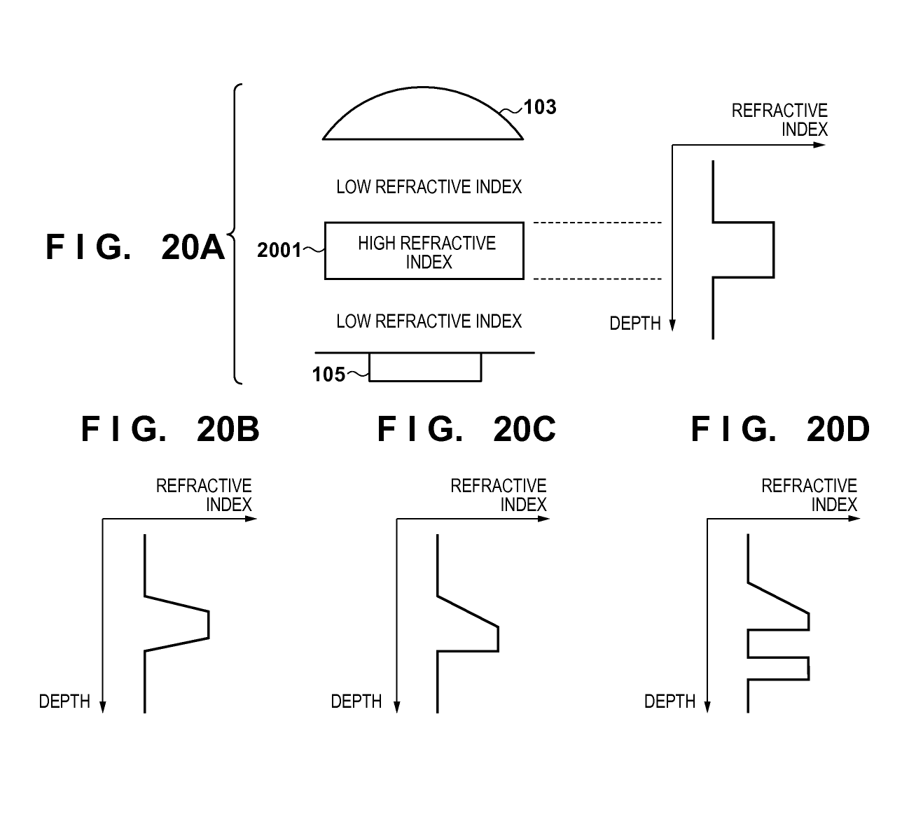

In this case, the exemplified arrangement has the parallel plate member 2001 provided on one of the insulating layers above the interconnection layer Mx. FIG. 20A shows the refractive index distribution of the member 20 in a direction perpendicular to the surface of the substrate 10. In this arrangement, the refractive index distribution of the member 20 including the parallel plate member 2001 includes one rectangular distribution. However, the present invention is not limited to this arrangement. For example, as shown in FIGS. 20A to 20D, the refractive index distribution of a plate-like high refractive index member 1901 may have a structure with a clear interface as shown in FIG. 20A, or a structure exhibiting a gradual change in refractive index as shown in FIG. 20B or 20C. Alternatively, a plurality of high refractive index materials may be stacked, instead of one high refractive index material, as shown in FIG. 20D, as long as the resultant distribution shortens the optical path length from a microlens to a photoelectric conversion portion.

This embodiment can obtain the same effects as those described in the fifth embodiment. In addition, the sixth embodiment reduces errors (for example, alignment errors) caused by manufacturing variations as compared with a case in which a plurality of lenses (microlenses and inner lenses) are formed for one pixel, and hence is also advantageous in terms of the manufacture.

### Seventh Embodiment

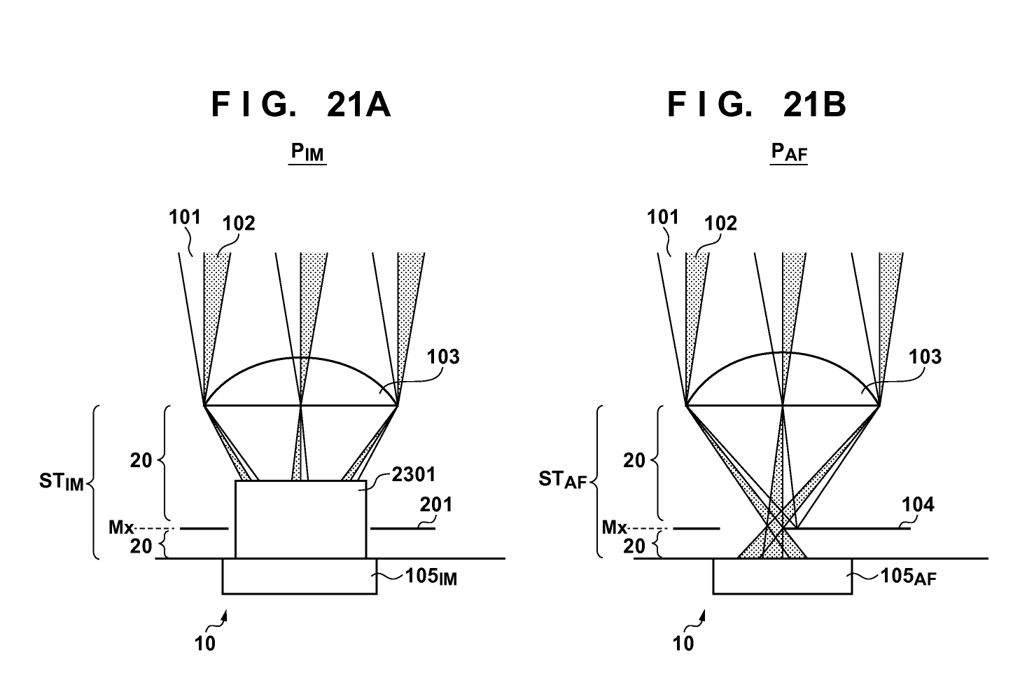

The sixth embodiment has exemplified the arrangement having the parallel plate member 2001 provided above the interconnection layer Mx in the member 20 of the pixel P_{IM} for imaging or the pixel P_{AF} for focus detection. However, a parallel plate member may also be provided below an interconnection layer Mx as long as a parallel plate member is provided at least above the interconnection layer Mx, as in the seventh embodiment. FIGS. 21A and 21B schematically show the sectional structures of a pixel P_{IM} for imaging and a pixel P_{AF} for focus detection according to this embodiment, respectively.

In this embodiment, in a structure S_{IM} of the pixel P_{IM} for imaging, a parallel plate member 2301 formed from a high refractive index member is provided from the upper surface of a substrate 10 to above the interconnection layer Mx. The parallel plate member 2301 is provided to have a width smaller than the opening formed in an interconnection portion 201. In this case, since the parallel plate member 2301 also has a function as the light guide portion of an optical waveguide, it is only required to make a light beam passing through a microlens 103_{IM} properly enter the parallel plate member 2301.

According to this embodiment, the parallel plate member 2301 also has a function as a light guide portion, and hence can obtain the same effects as those in the fifth and sixth embodiments while preventing color mixture between adjacent pixels. In addition, according to the embodiment, it is only required to make a light beam passing through the microlens 103_{IM} properly enter the parallel plate member 2301. Therefore, the degree of freedom in designing the microlens 103_{IM} and a microlens 103_{AF} is high. This is advantageous in terms of design.

As has been described above, according to the present invention, the microlenses 103 of the pixel P_{IM} for imaging and the pixel P_{AF} for focus detection which are adjacent to each other can be formed to have the same lens power (especially, the same lens shape and refractive index). This is advantageous in terms of the characteristics of the solid-state imaging apparatus I. Note that the three embodiments including the fifth to seventh embodiments have been described above. However, the present invention is not limited to them. The objects, states, applications, functions, and other specifications of the present invention can be changed as needed, and other embodiments can also implement the present invention. For example, a colorless member can be provided as a color filter layer for the pixel P_{AF} for focus detection.

(Imaging System)

The solid-state imaging apparatus included in an imaging system typified by a camera or the like has been described above. The concept of the imaging system includes not only an apparatus mainly designed to perform imaging but also an apparatus including an imaging function as an auxiliary function (for example, a personal computer or a portable terminal). The imaging system includes the solid-state imaging apparatus according to the present invention, which has been exemplified as each embodiment described above, and a processor (signal processor) which processes the signal output from the solid-state imaging apparatus. This processor includes an A/D converter and a processor which processes the digital data output from the A/D converter. Focus detection processing may be performed by the processor, or a focus detection processor which executes focus detection processing may be separately provided. Changes concerning this processing can be made, as needed.

While the present invention has been described with reference to exemplary embodiments, it is to be understood that the invention is not limited to the disclosed exemplary embodiments. The scope of the following claims is to be accorded the broadest in so as to encompass all such modifications and equivalent structures and functions.

This application claims the benefit of Japanese Patent Application No. 2013-129999 filed. Jun. 20, 2013, and No. 2013-130000 filed. Jun. 20, 2013, which are hereby incorporated by reference herein in their entirety.

What is claimed is:

1. A solid-state imaging apparatus comprising a pixel array, in which a pixel for imaging including a photoelectric conversion portion formed on a semiconductor substrate and a pixel for focus detection including a photoelectric conversion portion formed on the semiconductor substrate are arranged,
wherein the pixel for imaging and the pixel for focus detection each include a member including an insulating layer formed on the photoelectric conversion portion and a shielding portion, and a microlens provided on the member, and
the member of at least one of the pixel for imaging and the pixel for focus detection includes a flat plate-like member having a refractive index different from a refractive index of the insulating layer.

2. The apparatus according to claim 1, wherein
the flat plate-like member is provided across the interconnection layer from a lower side of the interconnection layer to an upper side of the interconnection layer.

3. The apparatus according to claim 1, wherein
at least one of conditions
that an integral value of a refractive index of the member of the pixel for imaging is larger than an integral value of a refractive index of the member of the pixel for focus detection, and
that an optical path length in the member of the pixel for imaging is larger than an optical path length in the member of the pixel for focus detection
is satisfied.

4. The apparatus according to claim 1, wherein
the member exhibits a change in refractive index in the flat plate-like member in a direction perpendicular to a surface of the substrate.

5. A solid-state imaging apparatus comprising a pixel array, in which a pixel for imaging including a photoelectric conversion portion formed on a semiconductor substrate and a pixel for focus detection including at least two photoelectric conversion portions formed on the semiconductor substrate are arranged,
wherein the pixel for imaging and the pixel for focus detection each include a member including an insulating layer formed on the photoelectric conversion portion, and a microlens provided on the insulating member, and
the member of at least one of the pixel for imaging and the pixel for focus detection includes a flat plate-like member having a refractive index different from a refractive index of the insulating layer.

6. The apparatus according to claim 1, wherein
the microlens of the pixel for imaging and the microlens of the pixel for focus detection are made of materials having the same refractive index and have the same shape.

7. A camera comprising:
a solid-state imaging apparatus defined in claim 1; and
a processor configured to process a signal output from the solid-state imaging apparatus.

8. A method of manufacturing a solid-state imaging apparatus including a pixel for imaging and a pixel for focus detection, the method comprising:
forming a member on a semiconductor substrate provided with a plurality of photoelectric conversion portions; and
forming the pixel for imaging and the pixel for focus detection by providing a plurality of microlenses in correspondence with the plurality of photoelectric conversion portions after the forming the member,
wherein the forming the member includes forming a flat plate-like member in at least one of the pixel for imaging and the pixel for focus detection.

9. The method according to claim 8, wherein
the forming the member includes forming a shielding portion in a portion serving as the pixel for focus detection, and
the shielding portion is located to make only a portion of a pupil image enter the photoelectric conversion portion of the pixel for focus detection.

10. The method according to claim 8, wherein
the pixel for imaging is provided with one photoelectric conversion portion of the plurality of photoelectric conversion portions and one microlens of the plurality of microlenses, and
the pixel for focus detection is provided with two photoelectric conversion portions of the plurality of photoelectric conversion portions and one of the plurality of microlenses.

11. The method according to claim 8, wherein
the forming the member includes forming a first insulating layer on the semiconductor substrate, forming a shielding portion on the first insulating layer, and forming a second insulating layer on the shielding portion, and
the flat plate-like member is formed on at least the second insulating layer of the first insulating layer and the second insulating layer.

12. An imaging device comprising a photoelectric conversion portion formed on a semiconductor substrate, and including a pixel for imaging and a pixel for focus detection which are arranged to be adjacent to each other,
wherein the pixel for imaging and the pixel for focus detection include microlenses having the same lens shape and the same refractive index, and structures including members formed between the microlenses and the semiconductor substrate and interconnection layers provided in the members,
the pixel for imaging has a first opening provided in the interconnection layer, and the pixel for focus detection has a second opening which is smaller than the first opening and is provided in the interconnection layer to perform phase-difference detection, and
the member of one of the pixel for imaging and the pixel for focus detection includes two members having different refractive indices, so as to locate an image forming position of the microlens at a first position nearer to the second opening than the photoelectric conversion portion in the pixel for focus detection and at a second position nearer to the photoelectric conversion portion than the first position in the pixel for imaging.

13. The device according to claim 12, wherein
an interface between the two members has a concave shape or a convex shape.

14. The device according to claim 12, wherein
an interface between the two members has a planar shape.

15. The device according to claim 14, wherein
one of the two members is provided across the interconnection layer from a lower side of the interconnection layer to an upper side of the interconnection layer.

16. The device according to claim 12, wherein
the pixel for imaging further includes a color filter layer provided below the microlens, and
the portions having the different refractive indices are provided below the color filter layer.

17. The device according to claim 12, wherein
the member includes a first side parallel to a light-receiving surface of the photoelectric conversion portion and a second side perpendicular to the light-receiving surface, and
the first side is longer than the second side.

18. The device according to claim 12, wherein the member includes a first side parallel to a light-receiving surface of the photoelectric conversion portion and a second side perpendicular to the light-receiving surface, and
the second side is longer than the first side.

19. The device according to claim 12, further comprising pads provided around the pixel for imaging and the pixel for focus detection.

20. An imaging apparatus comprising:
an imaging device defined in claim 19; and
a transmissive member provided on the imaging device.

21. A camera comprising:
an imaging device defined in claim 12; and
a processor configured to process a signal output from the imaging device.
